(19) United States
(12) Patent Application Publication
(10) Pub. No.: US 2020/0096534 A1
(43) Pub. Date: Mar. 26, 2020

(54) CHARGE OUTPUT STRUCTURE AND PIEZOELECTRIC ACCELERATION SENSOR THEREOF

(71) Applicant: FATRI United Testing & Control (Quanzhou) Technologies Co., Ltd., Quanzhou City (CN)

(72) Inventors: Nie Yongzhong, Quanzhou City (CN); Nie Chuan, Quanzhou City (CN); Liu Wenjie, Quanzhou City (CN)

(21) Appl. No.: 16/398,735

(22) Filed: Apr. 30, 2019

(30) Foreign Application Priority Data
Sep. 20, 2018 (CN) 201821544518.1

(51) Int. Cl. G01P 15/09; H01L 41/053; H01L 41/113

(52) U.S. Cl. CPC G01P 15/09; H01L 41/1132; H01L 41/0536

(57) ABSTRACT

The present application refers to the field of sensors, and in particular to a charge output structure, comprising a bracket, having a piezoelectric ceramic and a mass block successively arranged from inside to outside and radially sleeved thereon; and a pretightening member, sleeved on an outer periphery of the mass block and having an annular structure capable of applying a radial pretightening force to the piezoelectric ceramic and the mass block through shrinking with rise of temperature. Also provided is a piezoelectric acceleration sensor having the above charge output structure. The present application greatly enhances the contact stiffness of the whole structure, thereby achieves better frequency response and resonance of the whole structure.

### CROSS REFERENCE TO RELATED APPLICATIONS

This application claims priority to Chinese Patent Application No. 201821544518.1, filed on Sep. 20, 2018, the entire contents of which are incorporated herein by reference.

### TECHNICAL FIELD

The present application refers to the field of sensors, and in particular to a charge output structure and piezoelectric acceleration sensor thereof.

### BACKGROUND

The signal output by a piezoelectric acceleration sensor is proportional to the vibration acceleration of a system. The main problem is that use of different materials for assembling causes insufficiency of the global contact stiffness, thus resulting in low frequency response and low resonance. In order to ensure a firm assembling using different materials, currently, a widely used design is to use an epoxy adhesive bonding, which solves the problem of the bonding of different materials, but proposes high requirements for the quality of the epoxy adhesives between the bonding layers and the operation. If the epoxy adhesives contain impurities or bubbles are generated due to the operation, the global stiffness of the products may become insufficient, which reduces the global stiffness of the sensor. Since the adhesive process requires a long time of baking, the temperature of the piezoelectric acceleration sensor may become high, which affects the frequency response characteristics.

### SUMMARY

Therefore, the technical problem to be solved by the present application is to overcome the defects of insufficiency of the global stiffness of the product in the prior art, which affect the frequency response characteristics, thereby providing a charge output structure with high global stiffness and good frequency response and resonance, and a piezoelectric acceleration sensor thereof.

In order to solve the above technical problem, the present application provides a charge output structure, comprising a bracket, having a piezoelectric ceramic and a mass block successively arranged from inside to outside and radially sleeved thereon; and a pretightening member, sleeved on an outer periphery of the mass block and having an annular structure capable of applying a radial pretightening force to the piezoelectric ceramic and the mass block through shrinking with rise of temperature.

Further, the pretightening member is made of nickel-titanium memory alloy.

Further, the bracket comprises a supporting member, and a connecting member, disposed on the supporting member; and the piezoelectric ceramic, the mass block and the pretightening member are sleeved on the connecting member, and a gap is reserved between the piezoelectric ceramic, the mass block and the pretightening member and the supporting member.

Further, a top end of the connecting member is disposed flush with that of the piezoelectric ceramic and the mass block.

Further, a top end of the pretightening member is disposed higher than that of the mass block, the piezoelectric ceramic and the connecting member.

Further, the piezoelectric ceramic and the mass block are both annular structures formed by two monomers connected together.

Further, the mass block is made of stainless steel or tungsten-copper alloy.

Also provided is a piezoelectric acceleration sensor, comprising the charge output structure, further comprising a housing; wherein, the charge output structure is placed in the housing and has a predetermined distance from the housing.

1. In the charge output structure provided by the present application, the piezoelectric ceramic and the mass block are successively arranged from inside to outside and radially sleeved on the bracket, the pretightening member is sleeved on the outer periphery of the mass block, and is an annular structure having a capacity of shrinking with rise of temperature to apply a radial pretightening force to the piezoelectric ceramic and the mass block arranged inside the pretightening member when heated to a certain temperature. Since no connection layer and adhesive is formed between the members, the rigid connection between the structural members can be ensured, which enhances the pretightening force between the structural members in the assembling process, greatly enhances the contact stiffness of the whole structure, achieves better frequency response and resonance of the whole structure, and solves the problem that the frequency response characteristics are affected due to the insufficient global stiffness of the product.

2. In the charge output structure provided by the present application, the pretightening member is made of nickel-titanium memory alloy. The nickel-titanium memory alloy itself has properties such as high fatigue strength, high damping characteristics, and shrinking with rise of temperature, wear resistance, corrosion resistance, high damping and super elasticity, thus providing the possibility of applying a pretightening force.

3. In the charge output structure provided by the present application, the piezoelectric ceramic and the mass block are both annular structures formed by two monomers connected together, which have greater charge output than the integral structure of the prior art, and satisfy higher requirements for use.

4. In the charge output structure provided by the present application, the mass block is made of stainless steel or tungsten-copper alloy. The stainless steel or tungsten-copper alloy has the advantages of high strength, high specific gravity, high temperature resistance, arc ablation resistance, good electric and thermal conductivity and good processing performance, which may avoid degradation of the performance due to high temperature.

### BRIEF DESCRIPTION OF THE DRAWING

One or more embodiments are illustrated by way of example, and not by limitation, in the figures of the accompanying drawings, wherein elements having the same reference numeral designations represent like elements throughout. The drawings are not to scale, unless otherwise disclosed.

In order to more clearly illustrate the technical solutions of the embodiments of the present application or the prior art, the drawings used in the embodiments of the present application or the prior art will be briefly described below. Obviously, the drawings in the following description are only some embodiments of the present application, and those skilled in the art can obtain other drawings based on these drawings without any creative efforts.

FIG. 1 is a sectional view of the piezoelectric acceleration sensor provided by the present application;

FIG. 2 is a top view of the piezoelectric acceleration sensor provided by the present application;

FIG. 3 is a schematic view of the piezoelectric ceramic of FIG. 1;

FIG. 4 is a schematic view of the mass block of FIG. 1;

FIG. 5 is a schematic view of the pretightening member of FIG. 1.

In the drawings:

1—bracket; 10—supporting member; 11—connecting member; 2—piezoelectric ceramic; 3—mass block; 4—pretightening member; 5—housing.

### DETAILED DESCRIPTION

The technical solutions of the present application will be described clearly and completely with reference to the accompanying drawings. It is obvious that the described embodiments are only a part of the embodiments of the present application, and not all of the embodiments. All other embodiments obtained by those skilled in the art based on the embodiments of the present application without any creative efforts are within the scope of the present application.

Further, the technical features involved in the different embodiments of the present application described below may be combined with each other as long as they do not constitute a conflict with each other.

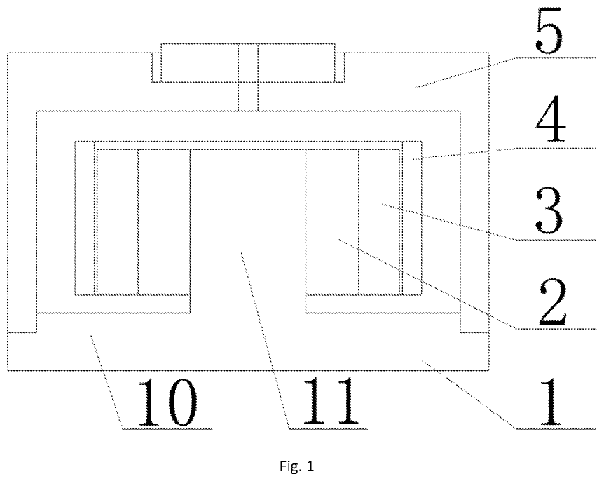

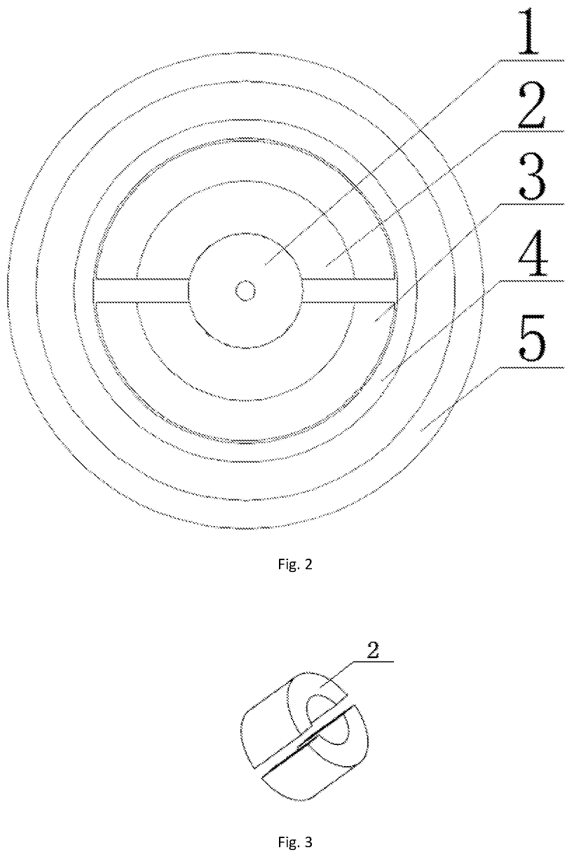

In an embodiment shown in FIGS. 1-2, a charge output structure comprises a bracket 1, having a piezoelectric ceramic 2 and a mass block 3 successively arranged from inside to outside and radially sleeved thereon; and a pretightening member 4, sleeved on an outer periphery of the mass block 3 and having an annular structure capable of applying a radial pretightening force to the piezoelectric ceramic 2 and the mass block 3 through shrinking with rise of temperature.

In the above charge output structure, the piezoelectric ceramic 2 and the mass block 3 are both an annular structure, and successively arranged from inside to outside and radially sleeved on the bracket 1, the pretightening member 4 is sleeved on the outer periphery of the mass block 3, and is an annular structure having a capacity of shrinking with rise of temperature to apply a radial pretightening force to the piezoelectric ceramic 2 and the mass block 3 arranged inside the pretightening member 4 when the pretightening member 4 is heated to a certain temperature. Since no connection layer and adhesive is formed between the members, the rigid connection between the structural members can be ensured, which enhances the pretightening force between the structural members in the assembling process, greatly enhances contact stiffness of the whole structure, and achieves better frequency response and resonance of the whole structure.

The pretightening member 4 is made of nickel-titanium memory alloy. The nickel-titanium memory alloy itself has properties such as high fatigue strength, high damping characteristics, capability of shrinking with rise of temperature, wear resistance, corrosion resistance, high damping and super elasticity.

The bracket 1 comprises a supporting member 10, and a connecting member 11 disposed on the supporting member 10. The supporting member 10 is a disc-shaped base. The connecting member 11 is integrally formed with the supporting member 10 and is a cylinder located at the center of the supporting member 10. The cylinder has a hollow interior for easy installation. The piezoelectric ceramic 2, the mass block 3 and the pretightening member 4 are sleeved on the connecting member 11, and a gap is reserved between the piezoelectric ceramic 2, the mass block 3 and the pretightening member 4 and the supporting member 10. The top end of the connecting member 11 is disposed flush with that of the piezoelectric ceramic 2 and the mass block 3. The connecting member 11 is disposed at the same height as the piezoelectric ceramic 2 and the mass block 3 to facilitate alignment with each other during mounting, and the mounting can be completed even without using an auxiliary tool. The top end of the pretightening member 4 is disposed higher than that of the mass block 3, the piezoelectric ceramic 2 and the connecting member 11.

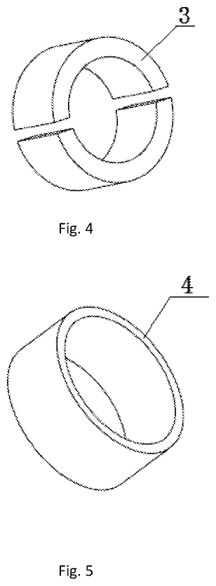

As shown in FIGS. 3-5, the piezoelectric ceramic 2 and the mass block 3 are both annular structures formed by two monomers connected together. The piezoelectric ceramic 2 and the mass block 3 are single monomers, and are designed as symmetrical semiannular structures, so the piezoelectric ceramic 2 and the mass block 3 can be closely connected together, which is convenient to install the mass block 3 and the piezoelectric ceramic 2 in the pretightening member 4. The symmetrical semiannular structures have greater charge output than the integral structure of the prior art, and satisfy higher requirements for use. The piezoelectric ceramic 2 and the mass block 3 have simple structures, are easy to process and suitable for mass production.

The mass block 3 is made of stainless steel or tungsten-copper alloy. The stainless steel or tungsten-copper alloy has the advantages of high strength, high specific gravity, high temperature resistance, arc ablation resistance, good electric and thermal conductivity and good processing performance, which may avoid degradation of the performance due to high temperature.

The present application also provides a piezoelectric acceleration sensor shown in FIG. 1, comprising a charge output structure, further comprising a housing 5; wherein the charge output structure is placed in the housing 5 and has a predetermined distance from the housing 5, i.e., neither the top end nor the side wall of the charge output structure is in contact with the housing 5.

It is apparent that the above embodiments are merely examples for clarity of illustration, and are not intended to limit the embodiments. Other variations or modifications of the various forms may be made by those skilled in the art in view of the above description. There is no need and no way to present all of the embodiments. The obvious variations or modifications derived therefrom are still within the scope of protection created by the present application.

What is claimed is:

1. A charge output structure, comprising a bracket, having a piezoelectric ceramic and a mass block successively arranged from inside to outside and radially sleeved thereon; and
a pretightening member, sleeved on an outer periphery of the mass block and having an annular structure capable of applying a radial pretightening force to the piezoelectric ceramic and the mass block through shrinking with rise of temperature.

2. The charge output structure of claim 1, wherein, the pretightening member is made of nickel-titanium memory alloy.

3. The charge output structure of claim 1, wherein, the bracket comprises
a supporting member, and
a connecting member, disposed on the supporting member; and
the piezoelectric ceramic, the mass block and the pretightening member are sleeved on the connecting member, and a gap is reserved between the piezoelectric ceramic, the mass block and the pretightening member and the supporting member.

4. The charge output structure of claim 3, wherein, a top end of the connecting member is disposed flush with that of the piezoelectric ceramic and the mass block.

5. The charge output structure of claim 4, wherein, a top end of the pretightening member is disposed higher than that of the mass block, the piezoelectric ceramic and the connecting member.

6. The charge output structure of claim 1, wherein, the piezoelectric ceramic and the mass block are both annular structures formed by two monomers connected together.

7. The charge output structure of claim 1, wherein, the mass block is made of stainless steel or tungsten-copper alloy.

8. A piezoelectric acceleration sensor, comprising
a charge output structure according to any one of claim 1,
further comprising a housing;
wherein, the charge output structure is placed in the housing and has a predetermined distance from the housing.
